(19) United States
(12) Patent Application Publication
(10) Pub. No.: US 2026/0082901 A1
(43) Pub. Date: Mar. 19, 2026

(54) METALLIZATION AIRGAP FOR SUBTRACTIVE METAL PROCESS

(71) Applicant: QUALCOMM Incorporated, San Diego, CA (US)

(72) Inventors: Junjing BAO, San Diego, CA (US); John Jianhong ZHU, San Diego, CA (US); Abhishek JAIN, San Diego, CA (US); Giridhar NALLAPATI, San Diego, CA (US)

(21) Appl. No.: 18/884,997

(22) Filed: Sep. 13, 2024

(51) Int. Cl. H01L 21/768; H01L 23/532

(52) U.S. Cl. CPC H10W 20/46; H10W 20/072; H10W 20/075; H10W 20/48

(57) ABSTRACT

A semiconductor structure having metallization airgaps for subtractive metal processes and a method for making the same are disclosed. In an aspect, the semiconductor structure includes metal traces disposed above an adhesion layer and separated from each other in a horizontal direction by one or more airgaps having a height H. A dielectric layer is disposed above the metal traces but not above the airgaps. An etch stop layer (ESL) is disposed above the first dielectric layer and the airgaps. Each airgap extends from the top surface of the adhesion layer to the bottom surface of the first ESL and has a width that extends in the second horizontal direction from a side surface of the first metal trace, from a side surface of the second metal trace, or from the first metal trace to the second metal trace, depending on the pitch of the metal traces.

### BACKGROUND OF THE DISCLOSURE

### 1. Field of the Disclosure

This disclosure relates generally to semiconductor wafer process, and more specifically to metallization airgaps without pinch-off for subtractive metal processes, and methods for making the same.

### 2. Description of the Related Art

Integrated circuit (IC) technology has achieved great strides in advancing computing power through miniaturization of electrical components. An IC device may be implemented in the form of an IC chip that has a set of circuits integrated thereon, including a plurality of active and passive components (e.g., transistors, diodes, capacitors, inductors, and/or resistors) and layers of contacts and interconnects above the active and passive components. In some aspects, the contacts and interconnects of an IC device are formed on the active and passive components on the front side of the IC device. As the sizes of the IC devices and the sizes of the components formed thereon become smaller, the available area for forming the contacts and interconnects also become smaller. As such, the routing complexity and/or the parasitic resistance and capacitance of the contacts and interconnects may increase and thus the manufacturing cost or the performance of the IC device may be negatively impacted.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a semiconductor structure includes an adhesion layer; a first metal trace and a second metal trace, disposed above the adhesion layer, extending in a vertical direction and in a first horizontal direction, and separated from each other in a second horizontal direction by one or more airgaps; a first dielectric layer, disposed above a top surface of the first metal trace and above a top surface of the second metal trace but not above the one or more airgaps; and a first etch stop layer (ESL) disposed above the first dielectric layer and the one or more airgaps, wherein each of the one or more airgaps has a height H that extends in the vertical direction from a top surface of the adhesion layer to a bottom surface of the first ESL and has a width that extends in the second horizontal direction from at least one of a side surface of the first metal trace or a side surface of the second metal trace.

In an aspect, a method for fabricating a semiconductor structure includes providing an adhesion layer, a metal layer disposed above the adhesion layer, and a first dielectric layer disposed above the metal layer; etching the metal layer and the first dielectric layer to form a first metal trace and a second metal trace extending in a vertical direction and in a first horizontal direction and separated from each other in a second horizontal direction, each metal trace comprising a first dielectric structure disposed on a top surface of the respective metal trace; forming, above the first metal trace, the second metal trace, and the respective dielectric structures, a first etch stop layer (ESL); and forming, between the first metal trace and the second metal trace, one or more airgaps, each airgap having a height H that extends in the vertical direction from a top surface of the adhesion layer to a bottom surface of the first ESL and each airgap having a width that extends in the second horizontal direction from at least one of a side surface of the first metal trace or a side surface of the second metal trace.

In an aspect, a semiconductor structure includes an adhesion layer; a first metal trace and a second metal trace in a metal layer-0 (M0), disposed above the adhesion layer, extending in a vertical direction and in a first horizontal direction, and separated from each other in a second horizontal direction; and a dielectric layer disposed above the adhesion layer, extending in the vertical direction and the first horizontal direction between the first metal trace and the second metal trace, wherein a first airgap is between the first metal trace and the dielectric layer and a second airgap is between the dielectric layer and the second metal trace.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, wherein like reference numbers represent like parts, which are presented solely for illustration and not limitation of the disclosure.

FIG. 1 is a cross-sectional view of a semiconductor structure having airgaps between metal layer-0 (M0) traces.

FIG. 2 is a cross-sectional view of a semiconductor structure having airgaps between metal traces according to aspects of the disclosure

FIGS. 3A-3J are cross-sections that illustrate steps in a process for fabricating a semiconductor structure having airgaps between metal traces according to aspects of the disclosure.

FIG. 4 is a flowchart of an example process associated with fabricating a semiconductor structure having airgaps between metal traces according to aspects of the disclosure.

FIG. 5 illustrates a mobile device in accordance with some examples of the disclosure.

FIG. 6 illustrates various electronic devices that may be integrated with any of the aforementioned integrated device or semiconductor device in accordance with various examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

A semiconductor structure having metallization airgaps for subtractive metal processes and a method for making the same are disclosed. In an aspect, the semiconductor structure comprises an adhesion layer, a first metal trace and a second metal trace, disposed above the adhesion layer, extending in a vertical direction and in a first horizontal direction, and separated from each other in a second horizontal direction by one or more airgaps, a first dielectric layer, disposed above a top surface of the first metal trace and above a top surface of the second metal trace but not above the one or more airgaps, and a first etch stop layer (ESL) disposed above the first dielectric layer and the one or more airgaps. Each of the one or more airgaps has a height H that extends in the vertical direction from a top surface of the adhesion layer to a bottom surface of the first ESL and has a minimum width W that extends in the second horizontal direction from at least one of a side surface of the first metal trace or a side surface of the second metal trace. In an aspect, the airgap is divided in the second horizontal direction by a dielectric structure disposed between, but not making contact with, the first metal trace and the second metal trace in the second horizontal direction, and extending in the vertical direction from the top surface of the adhesion layer to the bottom surface of the first ESL.

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

Various aspects relate generally to an integrated circuit device and a manufacturing method of making the integrated circuit device. Some aspects more specifically relate to semiconductor structures having metallization with airgaps for subtractive metal processes.

Particular aspects of the subject matter described in this disclosure can be implemented to realize one or more of the following potential advantages. An airgap is formed by forming, and then removing, a sacrificial dielectric deposited on the sidewall of the metal traces. The airgap so formed has a uniform, controlled height and may be formed in both narrow and wide spaces without pinch-off. In a narrow space (e.g., 1 times the minimum space), the airgap is between a first metal trace and a second metal trace adjacent to the first metal trace. In a wider space (e.g., some amount wider than the minimum space), a first airgap is between the first metal trace and a dielectric spacer and a second airgap is formed between the dielectric spacer and the second metal trace. The semiconductor structures so created have the double advantage of (a) the use of airgaps and (b) subtractive etch rather than the use of a damascene process to form metal interconnects. The techniques disclosed herein can be used in subtractive metal processes with less than 20 nm pitch for low resistance, and achieve lower capacitance by integrating the airgap into these subtractive metal etch processes.

The words “exemplary” and/or “example” are used herein to mean “serving as an example, instance, or illustration. ” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to”perform the described action.

As standard cell geometries “scale”, i.e., are reduced in size, the line pitch of metal layer-0 (M0) traces also becomes smaller. A M0 pitch of less than 20 nm is needed for continuous standard cell scaling below 2 nm node size. Copper (Cu) interconnects have low resistance but must be wrapped in a high resistivity barrier, such as tantalum nitride (TaN) to prevent diffusion of copper into adjacent structures, in a process referred to as a damascene process. Because the thickness of the high resistivity barrier must remain constant, as the M0 pitch is reduced the proportion of the high resistivity barrier to the copper conductor becomes higher, and interconnect resistance becomes increasingly larger.

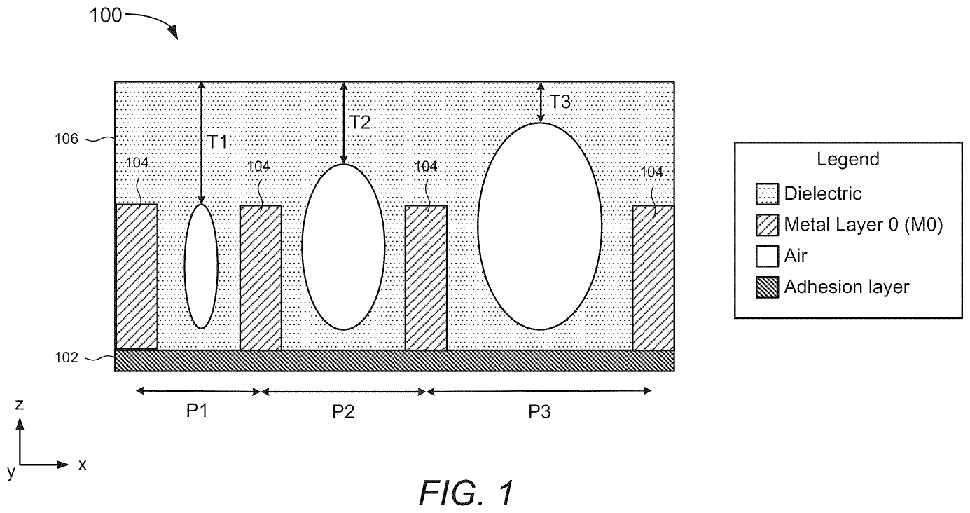

Alternative transition metals, such as molybdenum (Mo), osmium (Os), iridium (Ir), ruthenium (Ru), and rhodium (Rh), have been considered as promising candidates to replace copper as the back-end-of-line (BEOL) interconnect material. Compared with a damascene process, subtractive etch is better to achieve lower resistance due to larger grain size and less grain boundary scattering. In order to reduce metal capacitance, airgaps between metal traces are being attempted, but the size and height of the airgaps that result from the existing wafer processes varies according to the distance between the metal traces, which can result in pinch-off—where the dielectric above the airgap becomes too thin or disappears entirely—which reduces process yield and increases reliability risks. An example of this is shown in FIG. 1 is a cross-sectional view of a semiconductor structure 100 having airgaps between M0 traces. As shown in FIG. 1, the semiconductor structure 100 includes an adhesion layer 102, upon which have been fabricated a set of M0 traces 104 that are covered by a nonconformal dielectric 106. As shown in FIG. 1, the height of the airgap between a pair of traces—and thus the thickness of the dielectric layer above the airgap—varies depending on the distance between the pair of traces. In the example shown in FIG. 1, metal traces having a pitch P1 results in a thickness T1, metal traces having a larger pitch P2 results in a decreased thickness T2, and metal traces having an even larger pitch P3 results in a further decreased thickness T3. At some pitch larger than P3, the thickness may reach zero. This reduction of thickness of the dielectric above the airgap is referred to as pinch-off.

Techniques for fabricating metal interconnects and airgaps without pinch-off, and structures resulting from these techniques, are herein presented.

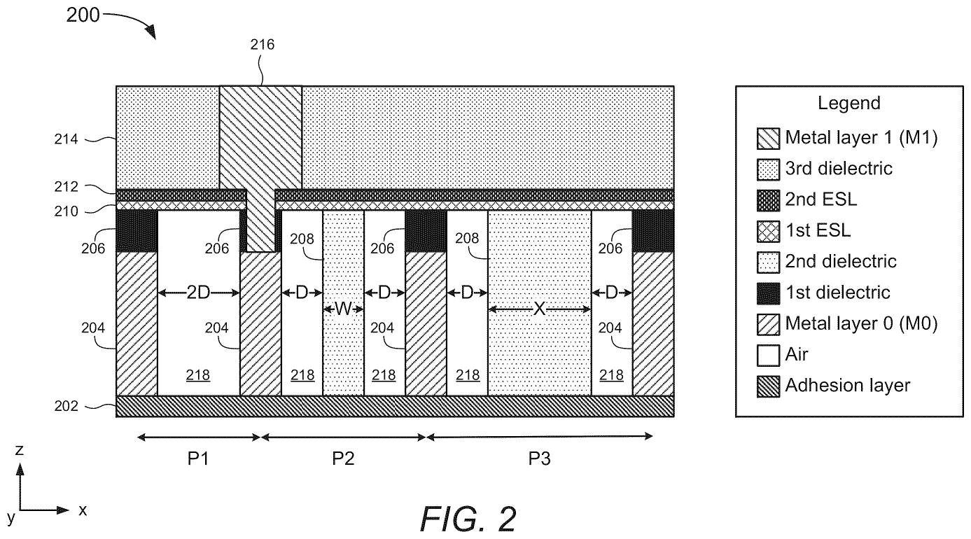

FIG. 2 is a cross-sectional view of a semiconductor structure 200 having airgaps between metal traces according to aspects of the disclosure. In the example shown in FIG. 2, the semiconductor structure 200 comprises an adhesion layer 202, a plurality of M0 traces 204 disposed above the adhesion layer 202 and each topped with a first dielectric layer 206 structure. A second dielectric layer 208 is disposed between pairs of M0 traces having a pitch greater than a first pitch P1, but not between pairs of M0 traces having a pitch of P1 or less. A first etch stop layer (ESL) 210 is disposed above the M0 traces 204, the first dielectric layer 206 structures, and the second dielectric layer 208 structures. In some aspects, the first ESL 210 may comprise silicon carbon oxynitride (SiCON). A second ESL 212 is disposed above the first ESL 210. In some aspects, the second ESL 212 may comprise SiCON, silicon carbon nitride (SiCN), aluminum nitride (AlN), or any combination thereof. A third dielectric layer 214 is disposed above the second ESL 212. In the example shown in FIG. 2, a metal layer-1 (M1) structure 216 makes contact with one of the M0 traces 204 through the third dielectric layer 214 and the first dielectric layer 206 structure above the M0 trace 204. The same principles may be applied to other metal layers, e.g., where the first metal trace and the second metal trace comprise metal layer-(N) and the metal contact structure comprises metal layer-(N+1).

As shown in FIG. 2, airgaps 218 exist between the adhesion layer 202 and the first ESL 210. At least one airgap 218 exists between each pair of M0 traces 204. In the example shown in FIG. 2, M0 traces having a pitch of P1 are separated by an airgap having a width of 2D; M0 traces having a pitch of P2>P1 are separated by a first airgap having a width of D, a second dielectric layer 208 structure having a width of W, and a second airgap also having a width of D; and M0 traces having a pitch of P3>P2 are separated by a first airgap having a width of D, a second dielectric layer 208 structure having a width of X>W, and a second airgap also having a width of D. Thus, in some aspects, there is always an airgap having a width of at least D immediately adjacent to each M0 trace, and where the pitch is less than or equal to 2D, the two airgaps merge into a single airgap of width 2D. In some aspects, where the pitch is greater than 2D, the space between the two airgaps is filled with a second dielectric layer 208 structure.

In some aspects, adjacent metal traces spaced apart by 10 nm or less are separated only by an airgap, and adjacent metal traces spaced apart by more than 10 nm are separated by a combination of airgap and dielectric material, with the airgaps being immediately adjacent to the metal traces—i.e., the dielectric material does not make contact with either of the metal traces. For example, in some aspects, adjacent metal traces spaced apart by 20 nm are separated by a 5 nm airgap, 10 nms of dielectric, and another 5 nm airgap.

As can be seen in FIG. 2, the height of the airgaps is uniform, and the thickness of the third dielectric layer 214 above each airgap does not vary depending on the distance between the pair of traces—that is, there is no pinch-off.

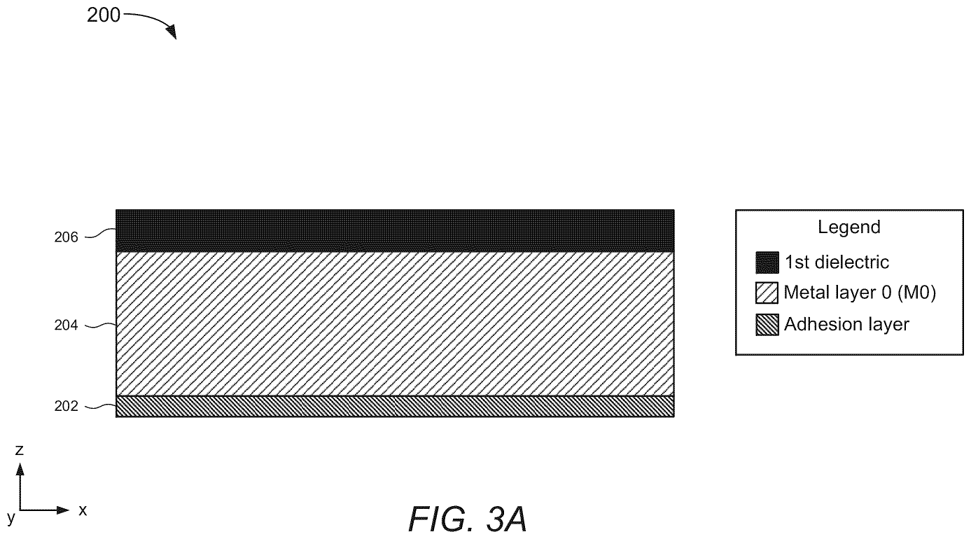

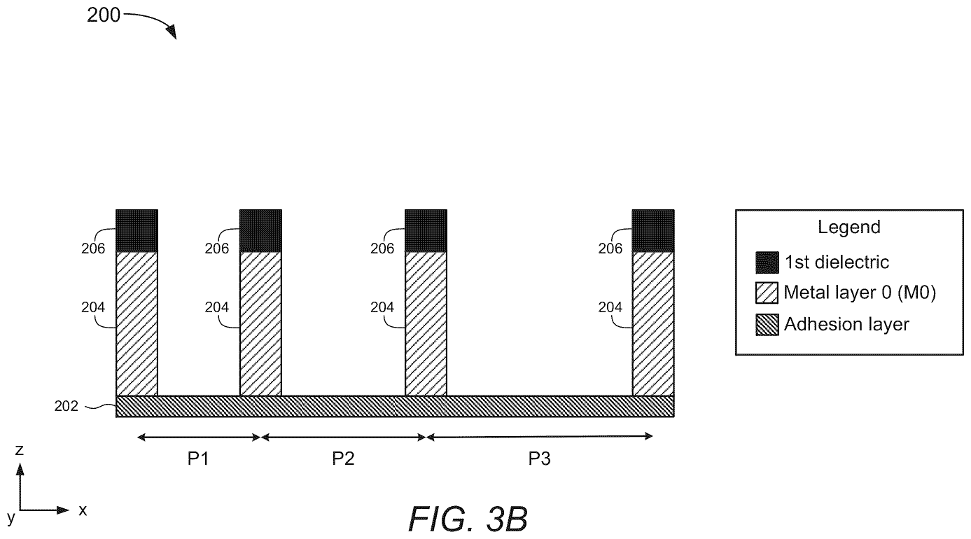

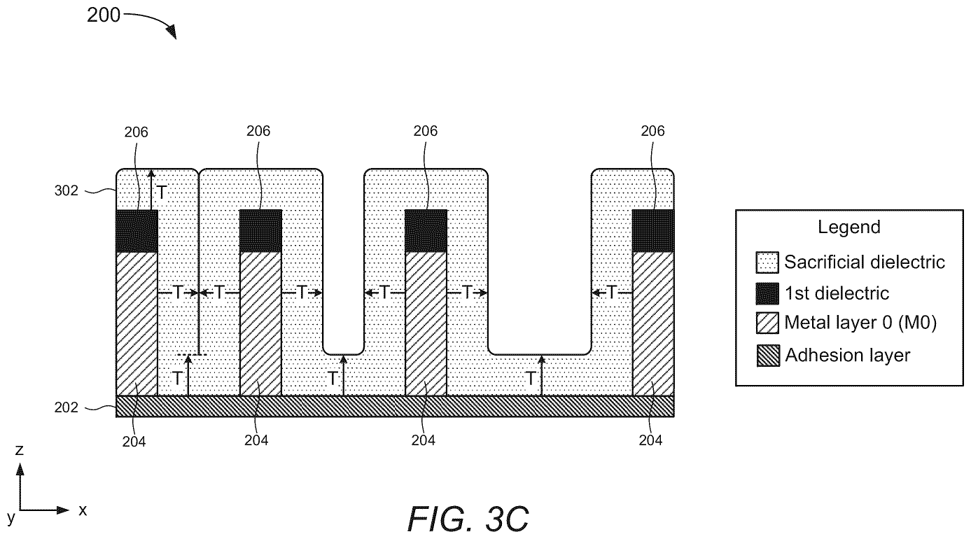

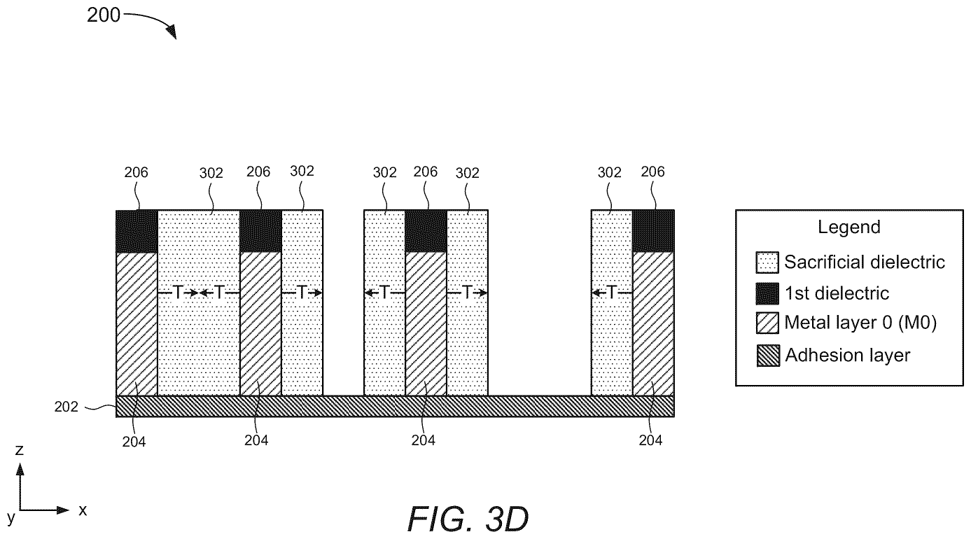

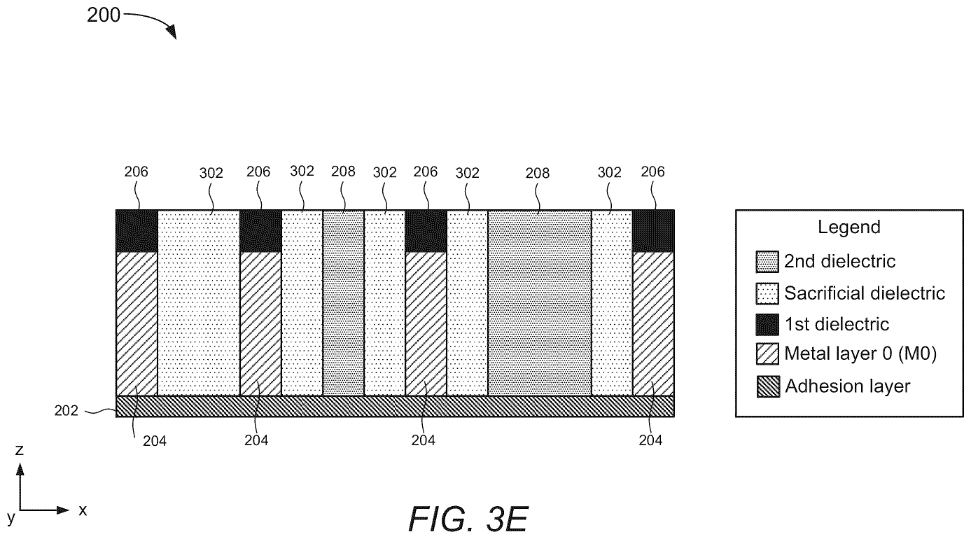

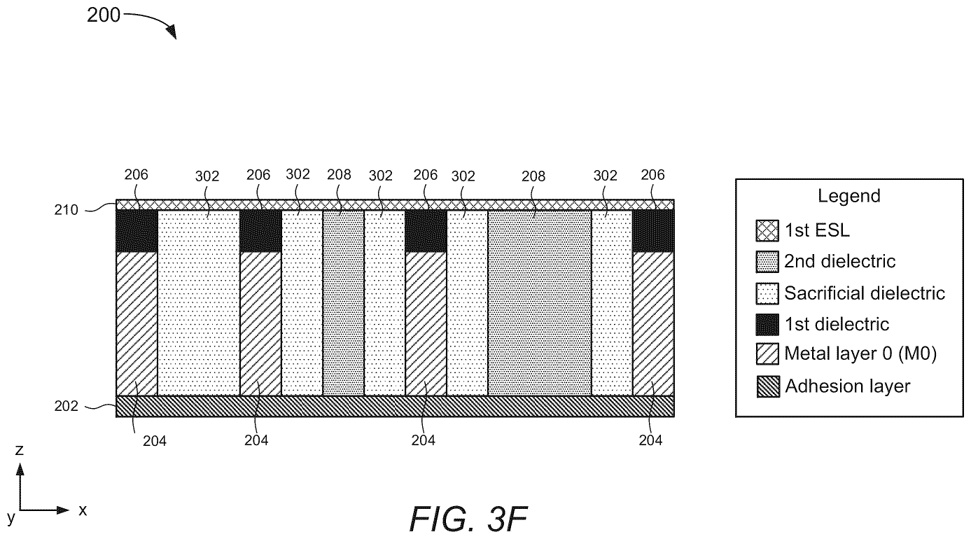

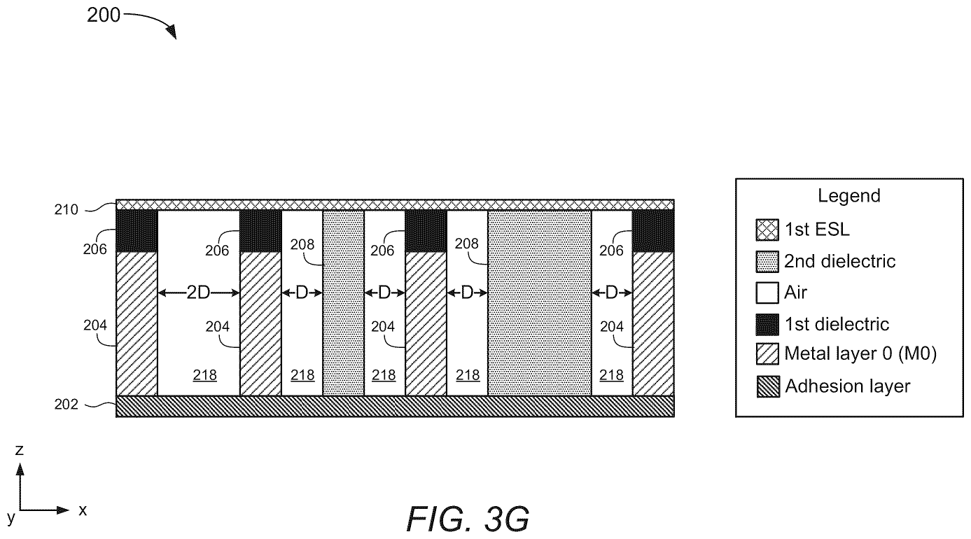

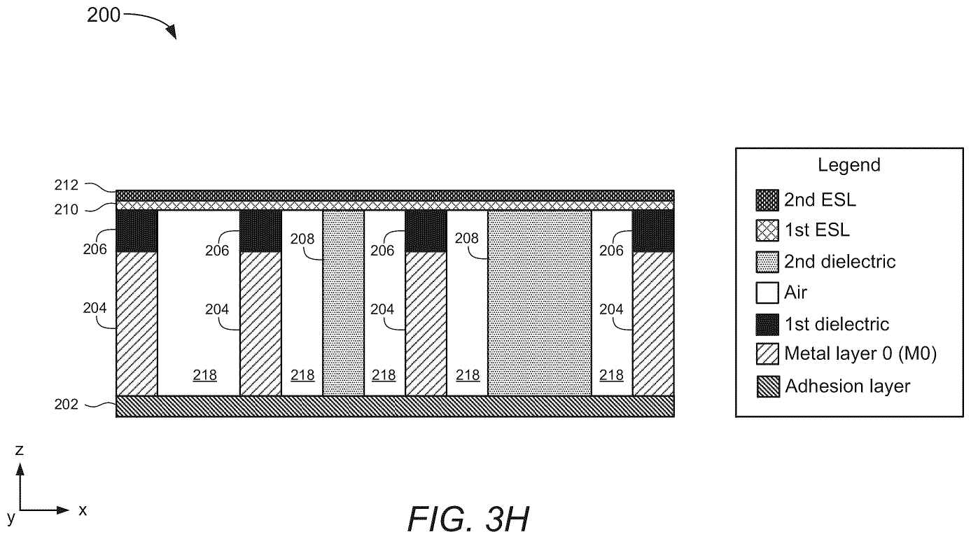

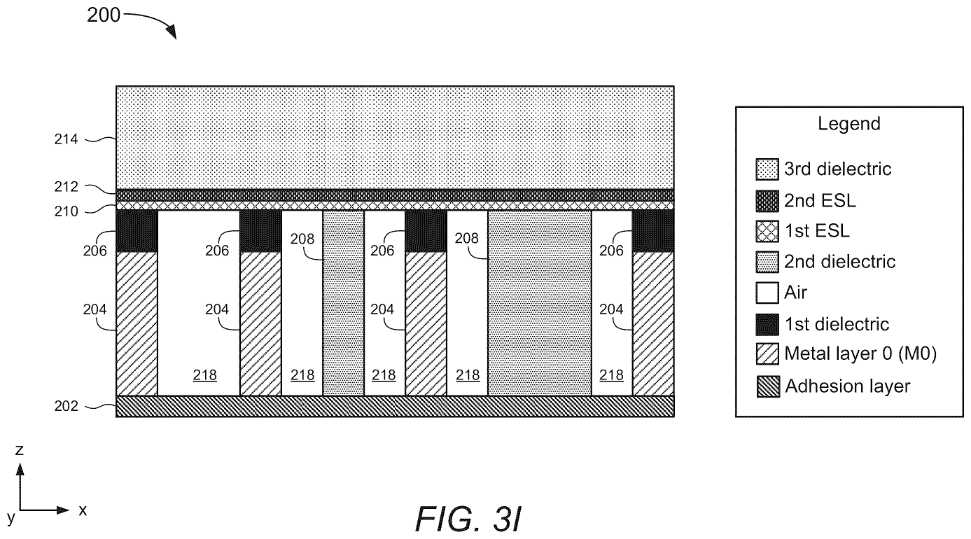

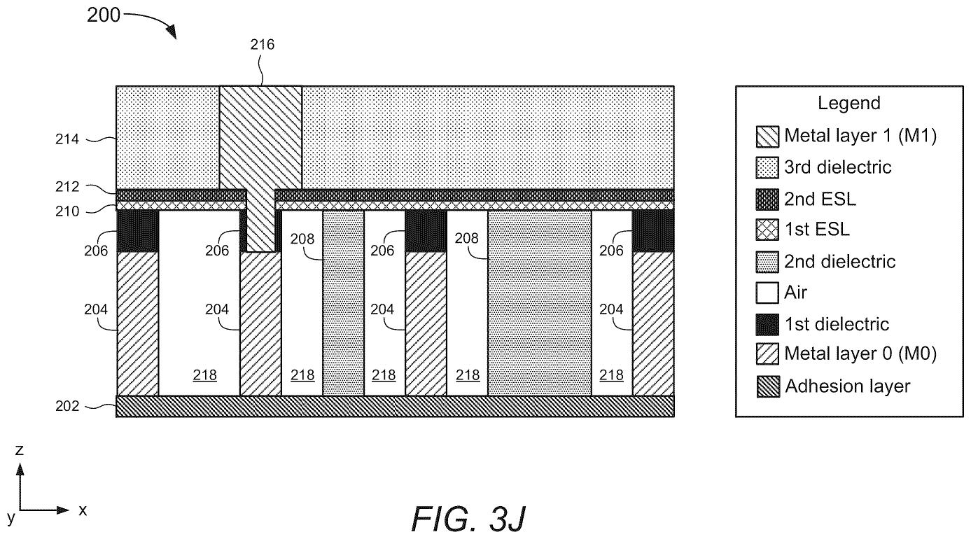

FIGS. 3A-3J are cross-sections that illustrate steps in a process for fabricating a semiconductor structure having airgaps between metal traces, according to aspects of the disclosure. The steps will be described with reference to structures illustrated in FIG. 2 where possible.

FIG. 3A shows the result after formation of an adhesion layer 202 for the purpose of promoting M0 growth, deposition of M0 metal 204 onto the adhesion layer 202, and formation of a first dielectric layer 206 above the M0 metal 204. In some aspects, the adhesion layer 202 comprises titanium nitride (TiN). In some aspects, the adhesion layer 202 may be deposited using atomic layer deposition (ALD). The adhesion layer is typically less than 1 nm thick. In some aspects, the thickness of the adhesion layer 202 may be approximately 0.3 nm. In some aspects, the M0 metal 204 comprises Mo, Os, Ir, Ru, or Rh. In some aspects, the M0 metal 204 may be formed via chemical vapor deposition (CVD) or plasma vapor deposition (PVD). In some aspects, the thickness of the M0 metal 204 layer may be approximately 30 nm. The first dielectric layer 206 is the via layer between M0 structures and M1 structures. In some aspects, the first dielectric layer 206 comprises silicon nitride (SiN). In some aspects, the first dielectric layer 206 may be formed via CVD. In some aspects, the thickness of the first dielectric layer 206 may be approximately 10 nm.

FIG. 3B shows the result after subtractive metal patterning. In some aspects, the subtractive metal patterning may be performed using chlorine (Cl) plasma. As shown in FIG. 3B, this produces the M0 traces 204. In the example shown in FIG. 3B, pairs of M0 traces 204 have different trace pitches, e.g., P1<P2<P3.

FIG. 3C shows the result after conformal deposition of a sacrificial material 302. In some aspects, the sacrificial material 302 comprises a sacrificial dielectric. In some aspects, the sacrificial dielectric comprises a material having the chemical formula C_{X}H_{Y}. The sacrificial material 302 covers the tops and sides of the first dielectric layer 206 structures, the sides of the M0 traces 204, and the top of the adhesion layer 202. In some aspects, the thickness of the sacrificial material 302 can be controlled in the conformal deposition process, for example such that the sacrificial material has a roughly uniform thickness where possible.

FIG. 3D shows the result after an anisotropic etch of the sacrificial material 302. This process etches the upward facing surfaces of the sacrificial material 302 until it is level with the top surface of the first dielectric layer 206 structures. In the example shown in FIG. 3D, this process also exposes portions of the adhesion layer between the M0 traces 204. Between M0 traces 204 having a pitch greater than P0, this process may produce columns of sacrificial material having approximately equivalent width.

FIG. 3E shows the result after conformal deposition of a second dielectric layer 208 to fill in the gaps between the M0 traces 204, followed by CMP planarization. Example materials used for the second dielectric layer 208 include, but are not limited to, materials comprised of Si, C, O, and H, such as organosilicate glass (SiCOH), silicon oxycarbide (SiOC), silicon dioxide (SiO2), etc.

FIG. 3F shows the result after deposition of a first ESL 210 having porous diffusion paths. In some aspects, the first ESL 210 comprises SiOC. In some aspects, the first ESL 210 has a porosity of greater than 20%. In some aspects, the ESL 210 is omitted. In some aspects, ESL 210 does not perform all functions of an etch stop layer and thus may be referred to as a transition layer.

FIG. 3G shows the result after removal of the sacrificial material 302. In some aspects, the sacrificial material 302 is removed by heating it to a temperature below 400 degrees Celsius, causing the sacrificial material 302 to burn and diffuse through the porous first ESL 210, leaving airgaps 218.

FIG. 3H shows the result after deposition of a second ESL 212. In some aspects, the second ESL 212 comprises aluminum oxide (AlO), SiN, SiOC, or a combination thereof. In some examples, the second ESL 212 is comprised of several materials and/or layers

FIG. 3I shows the result after deposition of a third dielectric layer 214. Example materials used for the third dielectric layer 214 include, but are not limited to, SiCOH, SiOC, SiO2 etc.

FIG. 3J shows the result after a M1 metallization process. In some aspects, the M1 metal can comprise Cu, cobalt (Co), Mo, Os, Ir, Ru, or Rh. In some aspects, the M1 metal may be a damascene process involving a liner layer, e.g., tantalum (Ta), TaN, or Co. As can be seen in FIG. 3J, the process may be controlled such that via formation is aligned with one of the M0 traces 204 to allow the surrounding M1 structure 216 to be of sufficient thickness to prevent spillage of metal in a contact structure into an adjacent airgap.

Although the example above illustrates fabrication of M0 interconnects with airgaps using a subtractive metal process, the same principles may be applied to metallization structures at other metal layers, and to metallization structures made as part of a frontside wafer process, which may be referred to herein as “frontside metallization structures,” or metallization structures made as part of a backside wafer process, which may be referred to herein as “backside metallization structures. ” A frontside wafer process generally involves the fabrication of active devices on a top, or front, surface of a wafer substrate, and a backside wafer process generally involves thinning or removing the wafer substrate from the bottom, or back, surface of the wafer, followed by the fabrication of power and signal routing structures that electrically connect to the active devices by means of through-substrate-vias (TSVs).

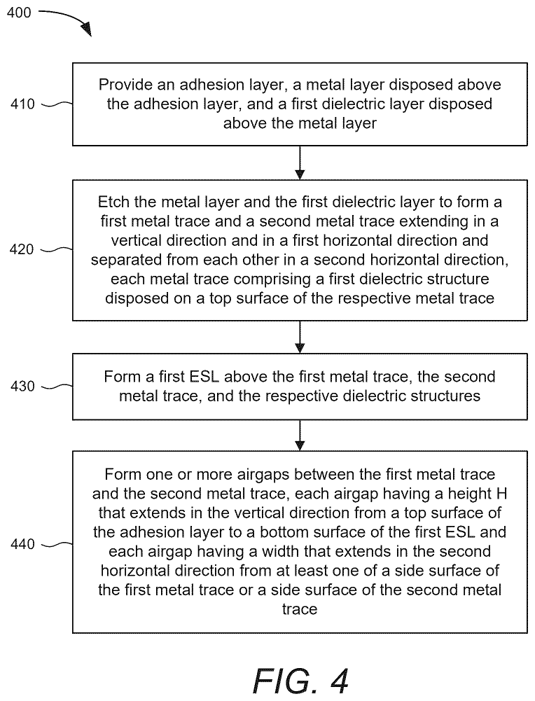

FIG. 4 is a flowchart of an example process 400 associated with fabricating a semiconductor structure having airgaps between metal traces according to aspects of the disclosure. As shown in FIG. 4, process 400 may include, at block 410, providing an adhesion layer, a metal layer disposed above the adhesion layer, and a first dielectric layer disposed above the metal layer.

As further shown in FIG. 4, process 400 may include, at block 420, etching the metal layer and the first dielectric layer to form a first metal trace and a second metal trace extending in a vertical direction and in a first horizontal direction and separated from each other in a second horizontal direction, each metal trace comprising a first dielectric structure disposed on a top surface of the respective metal trace.

As further shown in FIG. 4, process 400 may include, at block 430, forming a first etch stop layer (ESL), above first metal trace, the second metal trace, and their respective dielectric structures. Forming the first ESL may be pursuant to FIGS. 3F and/or 3H. Thus, the blocks 430 illustrated in FIG. 4 need not be performed in order and/or may be duplicated in the process 400.

As further shown in FIG. 4, process 400 may include, at block 440, forming one or more airgaps between the first metal trace and the second metal trace, each airgap having a height H that extends in the vertical direction from a top surface of the adhesion layer to a bottom surface of the first ESL and each airgap having a width that extends in the second horizontal direction from at least one of a side surface of the first metal trace or a side surface of the second metal trace.

In some aspects, forming the one or more airgaps comprises forming one airgap having a width ranging from a minimum width W to 2 W and extending in the second horizontal direction from the side surface of the first metal trace to the side surface of the second metal trace.

In some aspects, forming the one or more airgaps comprises forming a first airgap extending in the second horizontal direction from the side surface of the first metal trace towards the side surface of the second metal trace and a second airgap extending in the second horizontal direction from the side surface of the second metal trace towards the side surface of the first metal trace, and forming a second dielectric layer that is disposed in the second horizontal direction between the first airgap and the second airgap and that extends in the vertical direction from the top surface of the adhesion layer to the bottom surface of the ESL.

In some aspects, forming the one or more airgaps comprises conformally depositing a sacrificial material to cover the first metal trace, the second metal trace, and the adhesion layer, and anisotropically etching the sacrificial material to expose a top surface of the first metal trace, a top surface of the second metal trace, and a portion of the top surface of the adhesion layer between the first metal trace and the second metal trace, and wherein forming the one or more airgaps comprises removing the sacrificial material to produce the one or more airgaps in one or more volumes previously occupied by the sacrificial material. In some aspects, the sacrificial material is removed by burning it and allowing the combustion waste products to escape through a porous first ESL.

In some aspects, the process 400 further comprises forming a second ESL above the first ESL. In some aspects, the second ESL is formed above the first ESL after the sacrificial material has been removed. In some aspects, the second ESL is less porous than the first ESL.

In some aspects, the process 400 further comprises forming a third dielectric layer above the first ESL (and also over the second ESL, if present).

In some aspects, the process 400 further comprises forming a metal contact structure extending through the third dielectric layer and further extending from the bottom surface of the third dielectric layer to a top surface of the first metal trace (see, e.g., FIG. 3J).

Process 400 may include additional implementations, such as any single implementation or any combination of implementations described below and/or in connection with one or more other processes described elsewhere herein. Although FIG. 4 shows example blocks of process 400, in some implementations, process 400 may include additional blocks, fewer blocks, different blocks, or differently arranged blocks than those depicted in FIG. 4. Additionally, or alternatively, two or more of the blocks of process 400 may be performed in parallel.

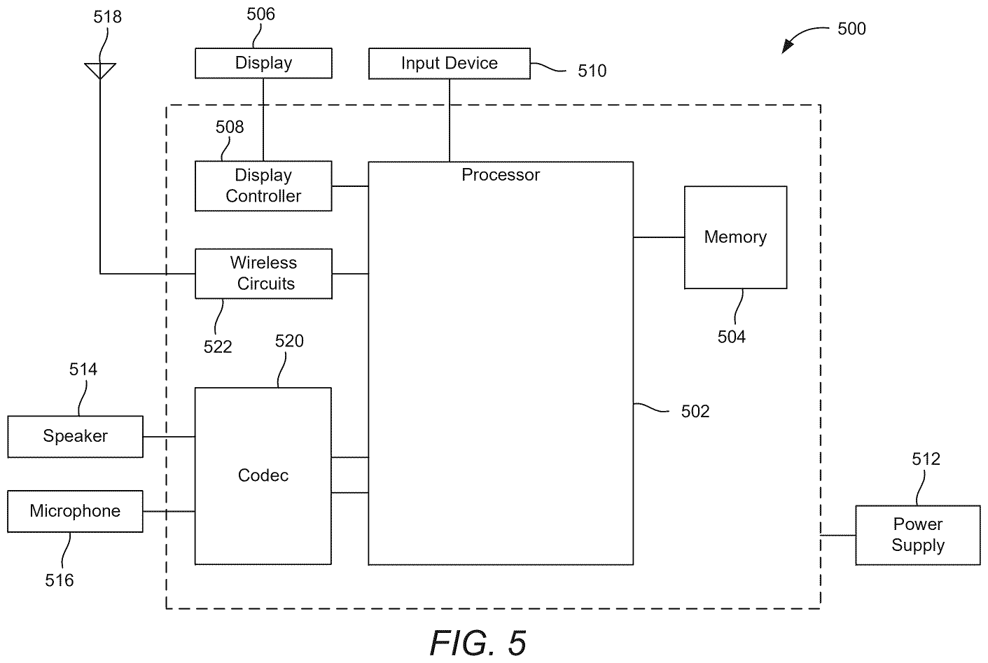

FIG. 5 illustrates a mobile device 500, according to aspects of the disclosure. In some aspects, the mobile device 500 may be implemented by including one or more IC devices manufactured based on the examples described in this disclosure.

In some aspects, mobile device 500 may be configured as a wireless communication device. As shown, mobile device 500 includes processor 502. Processor 502 may be communicatively coupled to memory 504 over a link, which may be a die-to-die or chip-to-chip link. Mobile device 500 also includes display 506 and display controller 508, with display controller 508 coupled to processor 502 and to display 506. The mobile device 500 may include input device 510 (e.g., physical, or virtual keyboard), power supply 512 (e.g., battery), speaker 514, microphone 516, and wireless antenna 518. In some aspects, the power supply 512 may directly or indirectly provide the supply voltage for operating some or all of the components of the mobile device 500.

In some aspects, FIG. 5 may include coder/decoder (CODEC) 520 (e.g., an audio and/or voice CODEC) coupled to processor 502; speaker 514 and microphone 516 coupled to CODEC 520; and wireless circuits 522 (which may include a modem, RF circuitry, filters, etc.) coupled to wireless antenna 518 and to processor 502.

In some aspects, one or more of processor 502, display controller 508, memory 504, CODEC 520, and wireless circuits 522 may include one or more IC devices including semiconductor structures manufactured according to the examples described in this disclosure.

It should be noted that although FIG. 5 depicts a mobile device 500, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

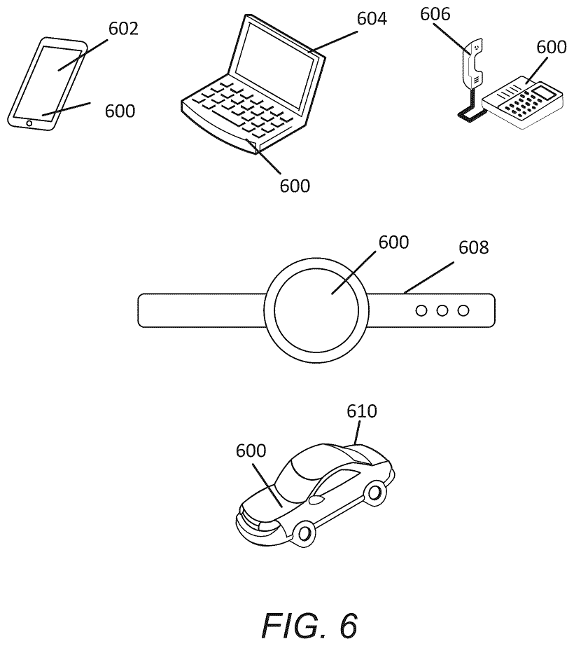

FIG. 6 illustrates various electronic devices that may be integrated with any of the aforementioned devices, semiconductor devices, integrated circuit (IC) packages, integrated circuit (IC) devices, semiconductor devices, integrated circuits, electronic components, interposer packages, package-on-package (PoP), System in Package (SiP), or System on Chip (SoC). For example, a mobile phone device 602, a laptop computer device 604, a fixed location terminal device 606, a wearable device 608, or automotive vehicle 610 may include a semiconductor device 600 (e.g., semiconductor structure 200) as described herein. The devices 602, 604, 606 and 608 and the vehicle 610 illustrated in FIG. 6 are merely exemplary. Other apparatuses or devices may also feature the semiconductor device 600 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. A semiconductor structure, comprising: an adhesion layer; a first metal trace and a second metal trace, disposed above the adhesion layer, extending in a vertical direction and in a first horizontal direction, and separated from each other in a second horizontal direction by one or more airgaps; a first dielectric layer, disposed above a top surface of the first metal trace and above a top surface of the second metal trace but not above the one or more airgaps; and a first etch stop layer (ESL) disposed above the first dielectric layer and the one or more airgaps, wherein each of the one or more airgaps has a height H that extends in the vertical direction from a top surface of the adhesion layer to a bottom surface of the first ESL and has a width that extends in the second horizontal direction from at least one of a side surface of the first metal trace or a side surface of the second metal trace.

Clause 2. The semiconductor structure of clause 1, wherein the one or more airgaps comprises one airgap having a width ranging from a minimum width W to 2 W and extending in the second horizontal direction from the side surface of the first metal trace to the side surface of the second metal trace.

Clause 3. The semiconductor structure of clause 2, wherein the one airgap has a width of 2 W.

Clause 4. The semiconductor structure of any of clauses 1 to 3, wherein the one or more airgaps comprises a first airgap extending in the second horizontal direction from the side surface of the first metal trace towards the side surface of the second metal trace and a second airgap extending in the second horizontal direction from the side surface of the second metal trace towards the side surface of the first metal trace, and wherein the semiconductor structure further comprises a second dielectric layer that is disposed in the second horizontal direction between the first airgap and the second airgap and that extends in the vertical direction from the top surface of the adhesion layer to the bottom surface of the first ESL.

Clause 5. The semiconductor structure of clause 4, wherein each of the first airgap and the second airgap has an approximately equal width, wherein no airgap between any metal layer-0 (M0) trace of the semiconductor structure is narrower the approximately equal width.

Clause 6. The semiconductor structure of any of clauses 4 to 5, wherein the second dielectric layer comprises at least one of organosilicate glass (SiCOH), silicon oxycarbide (SiOC), or silicon dioxide (SiO2).

Clause 7. The semiconductor structure of any of clauses 1 to 6, wherein the first ESL comprises silicon carbon oxynitride (SiCON).

Clause 8. The semiconductor structure of any of clauses 4 to 7, further comprising a third dielectric layer disposed above the first ESL.

Clause 9. The semiconductor structure of clause 8, further comprising a second ESL disposed between the first ESL and the third dielectric layer.

Clause 10. The semiconductor structure of clause 9, wherein the second ESL comprises at least one of silicon carbon nitride (SiCN), silicon carbon oxynitride (SiCON), or aluminum nitride (AlN).

Clause 11. The semiconductor structure of any of clauses 8 to 10, further comprising a metal contact structure extending through the third dielectric layer and further extending from the bottom surface of the third dielectric layer to a top surface of the first metal trace.

Clause 12. The semiconductor structure of clause 11, wherein the first metal trace and the second metal trace comprise metal layer-N and the metal contact structure comprises metal layer-N+1.

Clause 13. The semiconductor structure of any of clauses 1 to 12, wherein the first metal trace and the second metal trace comprise metal layer-0 (M0).

Clause 14. A method for fabricating a semiconductor structure, the method comprising: providing an adhesion layer, a metal layer disposed above the adhesion layer, and a first dielectric layer disposed above the metal layer; etching the metal layer and the first dielectric layer to form a first metal trace and a second metal trace extending in a vertical direction and in a first horizontal direction and separated from each other in a second horizontal direction, each metal trace comprising a first dielectric structure disposed on a top surface of the respective metal trace; forming, above the first metal trace, the second metal trace, and the respective dielectric structures, a first etch stop layer (ESL); and forming, between the first metal trace and the second metal trace, one or more airgaps, each airgap having a height H that extends in the vertical direction from a top surface of the adhesion layer to a bottom surface of the first ESL and each airgap having a width that extends in the second horizontal direction from at least one of a side surface of the first metal trace or a side surface of the second metal trace.

Clause 15. The method of clause 14, wherein forming the one or more airgaps comprises forming one airgap having a width ranging from a minimum width W to 2 W and extending in the second horizontal direction from the side surface of the first metal trace to the side surface of the second metal trace.

Clause 16. The method of any of clauses 14 to 15, wherein forming the one or more airgaps comprises forming a first airgap extending in the second horizontal direction from the side surface of the first metal trace towards the side surface of the second metal trace and a second airgap extending in the second horizontal direction from the side surface of the second metal trace towards the side surface of the first metal trace, and forming a second dielectric layer that is disposed in the second horizontal direction between the first airgap and the second airgap and that extends in the vertical direction from the top surface of the adhesion layer to the bottom surface of the first ESL.

Clause 17. The method of any of clauses 14 to 16, wherein forming the one or more airgaps comprises conformally depositing a sacrificial material to cover the first metal trace, the second metal trace, and the adhesion layer, and anisotropically etching the sacrificial material to expose a top surface of the first metal trace, a top surface of the second metal trace, and a portion of the top surface of the adhesion layer between the first metal trace and the second metal trace, and wherein forming the one or more airgaps comprises removing the sacrificial material to produce the one or more airgaps in one or more volumes previously occupied by the sacrificial material.

Clause 18. The method of any of clauses 14 to 17, further comprising forming a third dielectric layer above the first ESL and forming a metal contact structure extending through the third dielectric layer and further extending from the bottom surface of the third dielectric layer to a top surface of the first metal trace.

Clause 19. A semiconductor structure, comprising: an adhesion layer; a first metal trace and a second metal trace in a metal layer-0 (M0), disposed above the adhesion layer, extending in a vertical direction and in a first horizontal direction, and separated from each other in a second horizontal direction; and a dielectric layer disposed above the adhesion layer, extending in the vertical direction and the first horizontal direction between the first metal trace and the second metal trace, wherein a first airgap is between the first metal trace and the dielectric layer and a second airgap is between the dielectric layer and the second metal trace.

Clause 20. The semiconductor structure of clause 19, further comprising a third metal trace extending in the vertical direction and in the first horizontal direction, and separated from the second metal trace in the second horizontal direction by a third airgap, the third airgap extending in the second horizontal direction from a side surface of the third metal trace to a side surface of the second metal trace.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A semiconductor structure, comprising:
an adhesion layer;
a first metal trace and a second metal trace, disposed above the adhesion layer, extending in a vertical direction and in a first horizontal direction, and separated from each other in a second horizontal direction by one or more airgaps;
a first dielectric layer, disposed above a top surface of the first metal trace and above a top surface of the second metal trace but not above the one or more airgaps; and
a first etch stop layer (ESL) disposed above the first dielectric layer and the one or more airgaps,
wherein each of the one or more airgaps has a height H that extends in the vertical direction from a top surface of the adhesion layer to a bottom surface of the first ESL and has a width that extends in the second horizontal direction from at least one of a side surface of the first metal trace or a side surface of the second metal trace.

2. The semiconductor structure of claim 1, wherein the one or more airgaps comprises one airgap having a width ranging from a minimum width W to 2 W and extending in the second horizontal direction from the side surface of the first metal trace to the side surface of the second metal trace.

3. The semiconductor structure of claim 2, wherein the one airgap has a width of 2 W.

4. The semiconductor structure of claim 1, wherein the one or more airgaps comprises a first airgap extending in the second horizontal direction from the side surface of the first metal trace towards the side surface of the second metal trace and a second airgap extending in the second horizontal direction from the side surface of the second metal trace towards the side surface of the first metal trace, and wherein the semiconductor structure further comprises a second dielectric layer that is disposed in the second horizontal direction between the first airgap and the second airgap and that extends in the vertical direction from the top surface of the adhesion layer to the bottom surface of the first ESL.

5. The semiconductor structure of claim 4, wherein each of the first airgap and the second airgap has an approximately equal width, wherein no airgap between any metal layer-0 (M0) trace of the semiconductor structure is narrower the approximately equal width.

6. The semiconductor structure of claim 4, wherein the second dielectric layer comprises at least one of organosilicate glass (SiCOH), silicon oxycarbide (SiOC), or silicon dioxide (SiO2).

7. The semiconductor structure of claim 1, wherein the first ESL comprises silicon carbon oxynitride (SiCON).

8. The semiconductor structure of claim 4, further comprising a third dielectric layer disposed above the first ESL.

9. The semiconductor structure of claim 8, further comprising a second ESL disposed between the first ESL and the third dielectric layer.

10. The semiconductor structure of claim 9, wherein the second ESL comprises at least one of silicon carbon nitride (SiCN), silicon carbon oxynitride (SiCON), or aluminum nitride (AlN).

11. The semiconductor structure of claim 8, further comprising a metal contact structure extending through the third dielectric layer and further extending from the bottom surface of the third dielectric layer to a top surface of the first metal trace.

12. The semiconductor structure of claim 11, wherein the first metal trace and the second metal trace comprise metal layer-N and the metal contact structure comprises metal layer-N+1.

13. The semiconductor structure of claim 1, wherein the first metal trace and the second metal trace comprise metal layer-0 (M0).

14. A method for fabricating a semiconductor structure, the method comprising:
providing an adhesion layer, a metal layer disposed above the adhesion layer, and a first dielectric layer disposed above the metal layer;
etching the metal layer and the first dielectric layer to form a first metal trace and a second metal trace extending in a vertical direction and in a first horizontal direction and separated from each other in a second horizontal direction, each metal trace comprising a first dielectric structure disposed on a top surface of the respective metal trace;
forming, above the first metal trace, the second metal trace, and the respective dielectric structures, a first etch stop layer (ESL); and
forming, between the first metal trace and the second metal trace, one or more airgaps, each airgap having a height H that extends in the vertical direction from a top surface of the adhesion layer to a bottom surface of the first ESL and each airgap having a width that extends in the second horizontal direction from at least one of a side surface of the first metal trace or a side surface of the second metal trace.

15. The method of claim 14, wherein forming the one or more airgaps comprises forming one airgap having a width ranging from a minimum width W to 2 W and extending in the second horizontal direction from the side surface of the first metal trace to the side surface of the second metal trace.

16. The method of claim 14, wherein forming the one or more airgaps comprises forming a first airgap extending in the second horizontal direction from the side surface of the first metal trace towards the side surface of the second metal trace and a second airgap extending in the second horizontal direction from the side surface of the second metal trace towards the side surface of the first metal trace, and forming a second dielectric layer that is disposed in the second horizontal direction between the first airgap and the second airgap and that extends in the vertical direction from the top surface of the adhesion layer to the bottom surface of the first ESL.

17. The method of claim 14, wherein forming the one or more airgaps comprises conformally depositing a sacrificial material to cover the first metal trace, the second metal trace, and the adhesion layer, and anisotropically etching the sacrificial material to expose a top surface of the first metal trace, a top surface of the second metal trace, and a portion of the top surface of the adhesion layer between the first metal trace and the second metal trace, and wherein forming the one or more airgaps comprises removing the sacrificial material to produce the one or more airgaps in one or more volumes previously occupied by the sacrificial material.

18. The method of claim 14, further comprising forming a third dielectric layer above the first ESL and forming a metal contact structure extending through the third dielectric layer and further extending from the bottom surface of the third dielectric layer to a top surface of the first metal trace.

19. A semiconductor structure, comprising:
an adhesion layer;
a first metal trace and a second metal trace in a metal layer-0 (M0), disposed above the adhesion layer, extending in a vertical direction and in a first horizontal direction, and separated from each other in a second horizontal direction; and
a dielectric layer disposed above the adhesion layer, extending in the vertical direction and the first horizontal direction between the first metal trace and the second metal trace,
wherein a first airgap is between the first metal trace and the dielectric layer and a second airgap is between the dielectric layer and the second metal trace.

20. The semiconductor structure of claim 19, further comprising a third metal trace extending in the vertical direction and in the first horizontal direction, and separated from the second metal trace in the second horizontal direction by a third airgap, the third airgap extending in the second horizontal direction from a side surface of the third metal trace to a side surface of the second metal trace.
